(19) United States
(12) Patent Application Publication
(10) Pub. No.: US 2018/0076255 A1
(43) Pub. Date: Mar. 15, 2018

(54) SOLID-STATE IMAGE CAPTURING DEVICE AND ELECTRONIC APPARATUS

(71) Applicant: SEIKO EPSON CORPORATION, Tokyo (JP)

(72) Inventors: Kazunobu KUWAZAWA, Sakata-Shi (JP); Mitsuo SEKISAWA, Sakata-shi (JP); Noriyuki NAKAMURA, Sakata-shi (JP)

(73) Assignee: SEIKO EPSON CORPORATION, Tokyo (JP)

(21) Appl. No.: 15/699,173

(22) Filed: Sep. 8, 2017

(30) Foreign Application Priority Data
Sep. 15, 2016 (JP) 2016-180603
May 31, 2017 (JP) 2017-107554

(51) Int. Cl. H01L 27/146

(52) U.S. Cl. CPC H01L 27/14678; H01L 27/14623; H01L 27/14636; H01L 27/14627

(57) ABSTRACT

This solid-state image capturing device includes a light receiving element, a charge holding region, and a floating diffusion region that are arranged in a semiconductor substrate, a first transfer gate between the light receiving element and the charge holding region, a second transfer gate between the charge holding region and the floating diffusion region, an interconnect layer including an interconnect that is arranged on the semiconductor substrate via a plurality of interlayer insulating films, and a light shielding film that is arranged on the semiconductor substrate side relative to the interconnect layer and shields the charge holding region.

### BACKGROUND

### 1. Technical Field

The present invention relates to solid-state image capturing devices, electronic apparatuses using the same, and the like.

### 2. Related Art

In the past, it has been mainstream to use CCDs as solid state imaging elements, but in recent years, significant development has been made on CMOS sensors that can be driven at a low voltage and on which peripheral circuits can be mounted. As a result of taking measures in a manufacturing process such as employing a complete transfer technique and a dark current prevention structure and measures against noise in circuit techniques such as CDS (correlated double sampling), CMOS sensors have been improved and grown into devices surpassing that of CCDs in terms of both quality and quantity. Such significant advancement of CMOS sensors has been made possible by a significant improvement in image quality, and an improvement in charge transfer technique is one factor of this improvement.

As a related technique, a solid-state image capturing device in which a plurality of semiconductor elements that can realize complete transfer of signal charges are arranged as pixels and that has a high spatial resolution is disclosed in JP-A-2008-103647 (Paragraphs 0006-0007, FIG. 3). The semiconductor element includes a first conductivity type semiconductor region, a second conductivity type light receiving surface buried region that is buried in an upper portion of the semiconductor region and on which light is incident, a second conductivity type charge accumulation region that is buried in an upper portion of the semiconductor region and accumulates signal charges generated by the light receiving surface buried region, a charge read-out region that receives signal charges accumulated in the charge accumulation region, a first potential control means that transfers signal charges from the light receiving surface buried region to the charge accumulation region, and a second potential control means that transfers signal charges from the charge accumulation region to the charge read-out region.

A light shielding film 41 constituted by a metal thin film made of aluminum (Al) or the like that is provided on any of a plurality of interlayer insulating films that constitute a multi-layer interconnect structure is shown in FIG. 3 in JP-A-2008-103647 (Paragraphs 0006-0007, FIG. 3). An opening 42 in the light shielding film 41 is selectively provided such that photoelectric charges are generated in a semiconductor substrate 1 immediately under a light receiving cathode region 11a that constitutes a photodiode D1.

However, a charge accumulation region 12a that is located adjacent to the light receiving cathode region 11a may not be sufficiently shielded from light depending on the distance between the light shielding film 41 and the semiconductor substrate 1, and light is incident on the charge accumulation region 12a as well, and as a result, the amount of signal charges that are transferred to a charge read-out region 13 may fluctuate.

Also, due to capacitive coupling between the charge accumulation region (hereinafter, referred also as charge holding region) and an interconnect in an interconnect layer, the potential of the charge holding region is affected by the change in potential of a signal interconnect or a control interconnect in the interconnect layer, the potential distribution is disturbed, and the transfer characteristics may vary between pixels.

### SUMMARY

Some aspects of the invention relate to providing a solid-state image capturing device in which the fluctuation in the amount of signal charges caused by light that is incident on the charge holding region is reduced by improving the light shielding property of the charge holding region, and variation in the transfer characteristics that is caused by the potential of the charge holding region being influenced by the change in potential of the interconnect in the interconnect layer is reduced by reducing the capacitive coupling between the charge holding region and the interconnect in the interconnect layer. Furthermore, some aspects of the invention relate to providing an electronic apparatus or the like using such a solid-state image capturing device.

A solid-state image capturing device according to a first aspect of the invention includes: a light receiving element, a charge holding region, and a floating diffusion region that are arranged in a semiconductor substrate; a first transfer gate including a gate electrode that is arranged on a region between the light receiving element and the charge holding region in the semiconductor substrate via a gate insulating film; a second transfer gate including a gate electrode that is arranged on a region between the charge holding region and the floating diffusion region in the semiconductor substrate via a gate insulating film; an interconnect layer including an interconnect that is arranged on the semiconductor substrate via a plurality of interlayer insulating films; and a light shielding film that is arranged on the semiconductor substrate side relative to the interconnect layer, and shields the charge holding region from light.

According to the first aspect of the invention, as a result of arranging the light shielding film on the semiconductor substrate side relative to the interconnect layer, the fluctuation in the amount of signal charges caused by light that is incident on the charge holding region can be reduced by improving the light shielding property of the charge holding region. Also, the variation in the transfer characteristics that is caused by the potential of the charge holding region being influenced by the change in potential of the interconnect in the interconnect layer can be reduced by reducing the capacitive coupling between the charge holding region and the interconnect in the interconnect layer.

Here, the light shielding film may be electrically connected to the gate electrode of the first transfer gate. In that case, for example, when a control signal at a high level is supplied to the gate electrode of the first transfer gate, and the first transfer gate is turned on, the potential of the charge holding region increases due to the influence of the electric field formed by the light shielding film, and therefore it is easier to transfer electrons having negative charge from the light receiving element to the charge holding region.

Alternatively, the light shielding film may be electrically connected to the gate electrode of the second transfer gate. In that case, for example, when a control signal at a high level is supplied to the gate electrode of the first transfer gate, and the first transfer gate is turned on, a control signal at a low level is supplied to the gate electrode of the second transfer gate. Therefore, the influence of the change in potential of interconnects above the light shielding film exerted on the potential of the charge holding region can be reduced, and the potential distribution in the charge holding region can be stabilized.

Alternatively, the light shielding film may be electrically connected to an interconnect to which a low potential side power supply potential is supplied. In that case, the potential of the light shielding film is constant, and therefore the influence of the change in potential of interconnects above the light shielding film exerted on the potential of the charge holding region can be reduced, and the potential distribution in the charge holding region can be stabilized.

In that described above, the solid-state image capturing device may include four light receiving elements that are arranged in a row; four charge holding regions, four floating diffusion regions, four first transfer gates, and four second transfer gates that are arranged corresponding to the four light receiving elements; and a shielding layer that shields the four charge holding regions from light. The four floating diffusion regions may be electrically connected to a gate electrode of one buffer transistor. In that case, four charge holding regions can be shielded from light by one shielding layer.

Also, the solid-state image capturing device may further include an interconnect that is arranged at the same height as the light shielding film, in a region in which a logic circuit is arranged. In that case, the manufacturing process of the solid-state image capturing device can be simplified by forming the light shielding film and the interconnect in the logic circuit at the same time.

Alternatively, the light shielding film may be arranged in a layer that is different from an interconnect layer in a region in which a logic circuit is arranged. In that case, for example, as a result of arranging the light shielding film at a position that is lower than the interconnect in the logic circuit, the light shielding property of the charge holding region can be further improved, or the capacitive coupling between the interconnect in the interconnect layer and the charge holding region can be further reduced.

Furthermore, the light shielding film may include a first layer including aluminum or copper, and a second layer that is arranged on the first layer on the semiconductor substrate side of the first layer and includes titanium nitride. Titanium nitride has lower light reflectivity than aluminum, copper, or an alloy thereof. Accordingly, as a result of arranging the second layer including titanium nitride on the first layer on the semiconductor substrate side of the first layer, the amount of light that is incident on the charge holding region after having been reflected off the principal surface of the semiconductor substrate, and thereafter being reflected again off a lower surface of the light shielding film can be reduced.

Here, the film thickness of the second layer is desirably in a range from 50 nm to 80 nm. Accordingly, the second layer has the necessary and sufficient film thickness for exerting a property of titanium nitride off which light is unlikely to reflect. Also, the light shielding film may further include a third layer that is arranged on the second layer on the semiconductor substrate side of the second layer and includes titanium. In that case, the bondability of the second layer including titanium nitride to the base layer can be improved by the third layer including titanium.

An electronic apparatus according to a second aspect of the invention includes any of the solid-state image capturing devices described above. According to the second aspect of the invention, an electronic apparatus in which the image quality of image data that is obtained by capturing an image of a subject can be provided by using the solid-state image capturing device in which the fluctuation in the amount of signal charges caused by light that is incident on the charge holding region is reduced, and the variation in the transfer characteristic that is caused by the potential of the charge holding region being influenced by the change in potential of the interconnect in the interconnect layer is reduced.

### BRIEF DESCRIPTION OF THE DRAWINGS

The invention will be described with reference to the accompanying drawings, wherein like numbers reference like elements.

FIG. 1 is a perspective view illustrating an exemplary configuration of a CIS module.

FIG. 2 is a block diagram illustrating an exemplary configuration of a scanner device using the CIS module.

FIG. 3 is a block diagram illustrating an exemplary configuration of an image sensor chip.

FIG. 4 is a circuit diagram illustrating an equivalent circuit of a pixel unit and a read-out circuit unit corresponding to one pixel.

FIG. 5 is a circuit diagram illustrating an example of a unit block in a line sensor.

FIG. 6 is a plan view of a portion of a solid-state image capturing device according to a first embodiment of the invention.

FIG. 7 is a cross-sectional view taken along line VII-VII in FIG. 6.

FIG. 8 is a cross-sectional view of a portion of a solid-state image capturing device according to a second embodiment of the invention.

FIG. 9 is a cross-sectional view of a portion of a solid-state image capturing device according to a third embodiment of the invention.

FIG. 10 is a plan view of a portion of a solid-state image capturing device according to a modification of the first embodiment of the invention.

FIG. 11 is a plan view illustrating a light shielding film that is arranged continuously over a plurality of unit blocks.

FIG. 12 is a plan view of a portion of a solid-state image capturing device according to a modification of the second embodiment of the invention.

FIG. 13 is a plan view of a portion of a solid-state image capturing device according to a modification of the third embodiment of the invention.

FIG. 14 is a plan view of a portion of a solid-state image capturing device according to a fourth embodiment of the invention.

FIG. 15 is a cross-sectional view taken along line XV-XV in FIG. 14.

FIG. 16 is a plan view of a portion of a solid-state image capturing device according to a modification of the fourth embodiment of the invention.

FIG. 17 is a cross-sectional view of a solid-state image capturing device according to a fifth embodiment of the invention.

FIG. 18 is a cross-sectional view illustrating an example of a light shielding film.

### DESCRIPTION OF EXEMPLARY EMBODIMENTS

Hereinafter, embodiments of the invention will be described in detail with reference to the drawings. The same constituent elements are given the same reference numerals, and a redundant description is omitted.

Electronic Apparatus

Hereinafter, a CIS type scanner device using a contact image sensor (CIS) module including a solid-state image capturing device (image sensor chip) according to any of the embodiments of the invention will be described as an electronic apparatus according to one embodiment of the invention.

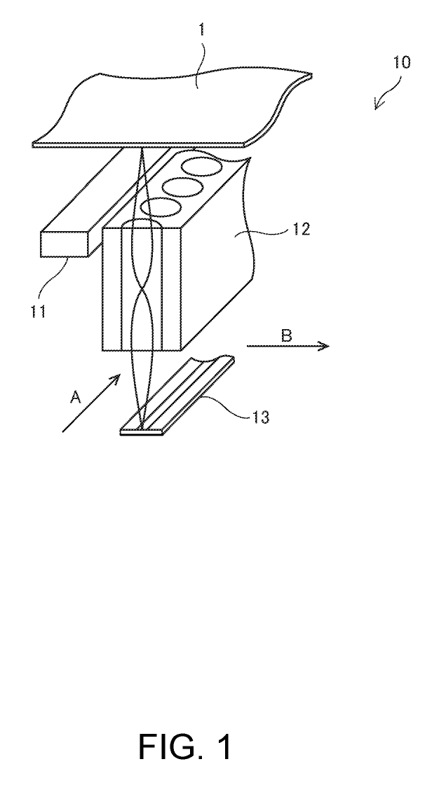

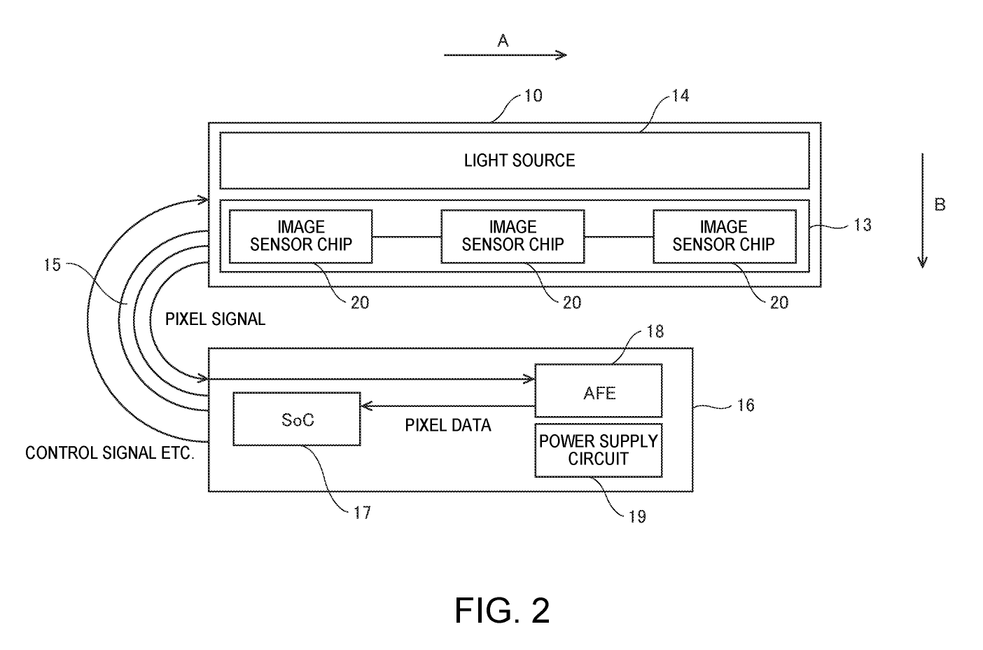

FIG. 1 is a perspective view illustrating an exemplary configuration of a CIS module, and FIG. 2 is a block diagram illustrating an exemplary configuration of a scanner device using the CIS module shown in FIG. 1. As shown in FIG. 1, a CIS module 10 includes a light guide 11 that irradiates a document 1 with light, a lens array 12 that forms an image using light reflected from the document 1, and an image sensor 13 that includes light receiving elements such as photodiodes arranged at a position where the image is formed.

With reference to FIGS. 1 and 2, the CIS module 10 includes a light source 14 that generates light that is to be incident on an end portion of the light guide 11. In the case of a color scanner, the light source 14 includes red (R), green (G), and blue (B) LEDs. The LEDs of three colors are pulse-lighted in a time division manner. The light guide 11 guides light such that a region of the document 1 along the main scanning direction A is irradiated with light generated by the light source 14.

The lens array 12 is constituted by a rod lens array or the like, for example. The image sensor 13 includes a plurality of pixels along the main scanning direction A, and moves in the sub scanning direction B along with the light guide 11 and the lens array 12.

As shown in FIG. 2, the image sensor 13 may be constituted by a plurality of image sensor chips 20 connected in series. The CIS module 10 that can move in the sub scanning direction B is connected to a main board 16 that is fixed to the scanner device via a flexible wiring 15. A system on chip (SoC) 17, an analog front end (AFE) 18, and a power supply circuit 19 are mounted on the main board 16.

The system on chip 17 supplies a control signal, a clock signal, and the like to the CIS module 10. A pixel signal generated by the CIS module 10 is supplied to the analog front end 18. The analog front end 18 performs analog/digital conversion on an analog pixel signal, and outputs digital pixel data to the system on chip 17.

The power supply circuit 19 supplies a power supply voltage to the system on chip 17 and the analog front end 18, and supplies a power supply voltage, a reference voltage, and the like to the CIS module 10. Note that portions of the analog front end 18 and the power supply circuit 19, or a light source driver and the like may be mounted on the CIS module 10.

Solid-State Image Capturing Device

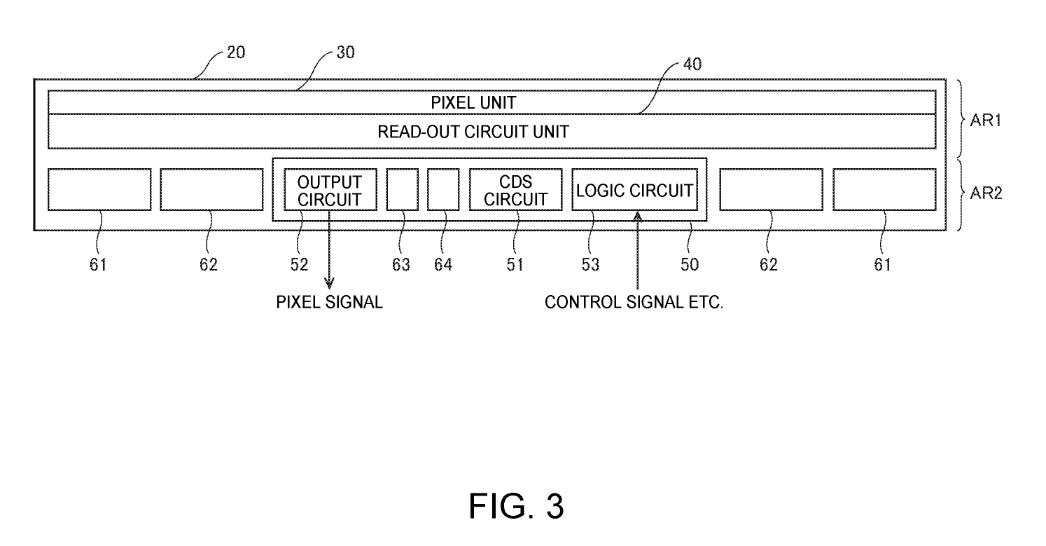

FIG. 3 is a block diagram illustrating an exemplary configuration of an image sensor chip that is a solid-state image capturing device according to any of the embodiments of the invention. As shown in FIG. 3, the image sensor chip 20 includes a pixel unit 30, a read-out circuit unit 40, and a control circuit unit 50, and may further include capacitors 61 to 64.

In the pixel unit 30, a light receiving element (photodiode, for example) is arranged in each of a plurality of pixels. The read-out circuit unit 40 reads out pixel information by converting a signal charge that is output from the pixel unit 30 to a signal voltage. The control circuit unit 50 performs control so as to generate a pixel signal based on an output voltage of the read-out circuit unit 40. For example, the control circuit unit 50 includes a correlated double sampling (CDS: correlated double sampling) circuit 51, an output circuit 52, and a logic circuit 53.

The correlated double sampling circuit 51 performs correlated double sampling processing on the output voltage of the read-out circuit unit 40. That is, the correlated double sampling circuit 51 samples a voltage immediately after reset and a voltage after exposure, and cancels reset noise by performing processing for obtaining the difference between the sampled voltages, and generates an output voltage according to the intensity of light. The output circuit 52 generates a pixel signal based on the output voltage of the correlated double sampling circuit 51, and outputs the pixel signal. The logic circuit 53 is supplied with a control signal, a clock signal, and the like from the system on chip 17 shown in FIG. 2.

The capacitors 61 are connected between an interconnect of a high potential side power supply potential and an interconnect of a low potential side power supply potential that are arranged in a first region AR1 of the image sensor chip 20, and stabilizes a power supply voltage. Also, the capacitors 62 to 64 are connected between an interconnect of the high potential side power supply potential and an interconnect of the low potential side power supply potential that are arranged in a second region AR2 of the image sensor chip 20, and stabilize the power supply voltage.

Pixel Unit and Read-Out Circuit Unit

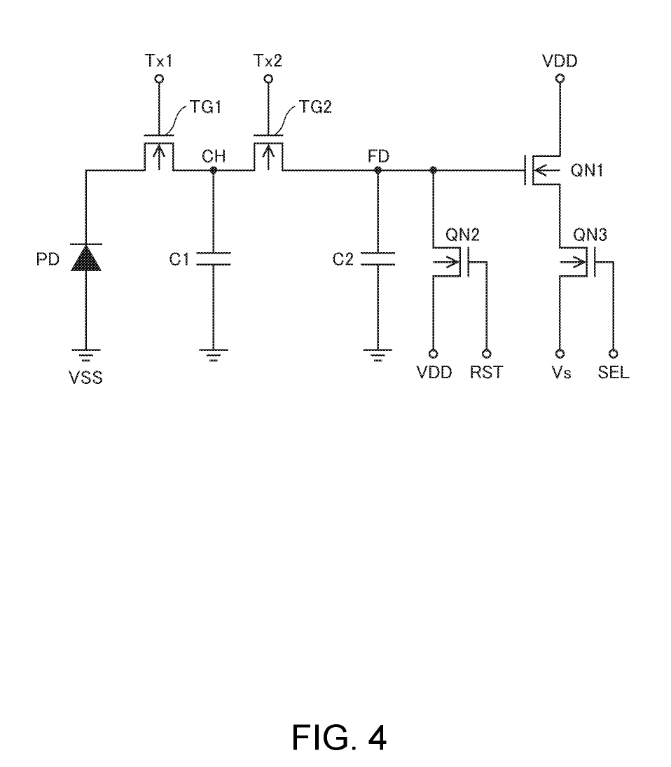

FIG. 4 is a circuit diagram illustrating an equivalent circuit of a pixel unit and a read-out circuit unit corresponding to one pixel. A photodiode PD, for example, is arranged in one pixel of the pixel unit 30 shown in FIG. 3, as a light receiving element having a photoelectric conversion function. The photodiode PD generates signal charges according to the intensity of light that is incident thereon, and accumulates the signal charges.

In order to read out signal charges from the photodiode PD, the read-out circuit unit 40 shown in FIG. 3 includes a pre-stage transfer gate TG1, which is a first transfer gate, a charge holding capacitor C1, a post-stage transfer gate TG2, which is a second transfer gate, and a charge holding capacitor C2. Furthermore, the read-out circuit unit 40 includes a transistor (referred to also as buffer transistor, in the present application) QN1 that constitutes a read-out buffer amplifier, a reset transistor QN2, and a selection transistor QN3. Note that, in the case where an analog shift register is provided at the last stage of the read-out circuit unit 40 in a line sensor, the selection transistor QN3 may be included in the analog shift register.

Here, the pre-stage transfer gate TG1 is constituted by an N-channel MOS transistor whose source and drain are a cathode of the photodiode PD and a cathode (charge holding region CH) of a storage diode. Also, the storage diode constitutes the charge holding capacitor C1.

Furthermore, the post-stage transfer gate TG2 is constituted by an N-channel MOS transistor whose source and drain are the charge holding region CH and an N-type floating diffusion region (floating diffusion) FD arranged in a P-type semiconductor layer. Also, the P-type semiconductor layer and the N-type floating diffusion region FD constitute the charge holding capacitor C2. Note that, in the present application, the semiconductor layer refers to a semiconductor substrate, a well formed in the semiconductor substrate, or an epitaxial layer formed on the semiconductor substrate.

The photodiode PD, the pre-stage transfer gate TG1, and the post-stage transfer gate TG2 are connected in series between an interconnect of a low potential side power supply potential VSS, and a gate electrode of the buffer transistor QN1. Also, a drain of the buffer transistor QN1 is connected to an interconnect of a high potential side power supply potential VDD. In the following, the power supply potential VSS is assumed to be ground potential 0V.

The reset transistor QN2 has a drain connected to the interconnect of the power supply potential VDD, a source connected to the gate electrode of the buffer transistor QN1, and a gate electrode to which a reset signal RST is supplied. Also, the selection transistor QN3 has a drain connected to a source of the buffer transistor QN1, a source connected to an output terminal of the read-out circuit unit 40, and a gate electrode to which a pixel selection signal SEL is supplied.

The pre-stage transfer gate TG1 transfers the signal charges accumulated in the photodiode PD to the charge holding capacitor C1 when a control signal Tx1 is activated to a high level. The charge holding capacitor C1 holds the signal charges transferred by the pre-stage transfer gate TG1. After the control signal Tx1 is inactivated to a low level, a control signal Tx2 is activated to a high level. The post-stage transfer gate TG2 transfers the signal charge held in the charge holding capacitor C1 to the charge holding capacitor C2 when a control signal Tx2 is activated to a high level. The charge holding capacitor C2 holds the signal charge transferred by the post-stage transfer gate TG2, and converts the signal charges into a signal voltage.

The reset transistor QN2 resets the gate potential of the buffer transistor QN1 to an initial state potential (power supply potential VDD, for example), when the reset signal RST is activated to a high level. When the reset is released, the buffer transistor QN1 outputs an output voltage according to the signal voltage across the charge holding capacitor C2 from the source.

The selection transistor QN3 selects the output voltage of the buffer transistor QN1 when the pixel selection signal SEL is activated to a high level. Accordingly, the output voltage of the buffer transistor QN1 is output to the output terminal of the read-out circuit unit 40 via the selection transistor QN3, and an output voltage Vs is thereby generated.

Unit Block of Pixel Unit and Read-Out Circuit Unit

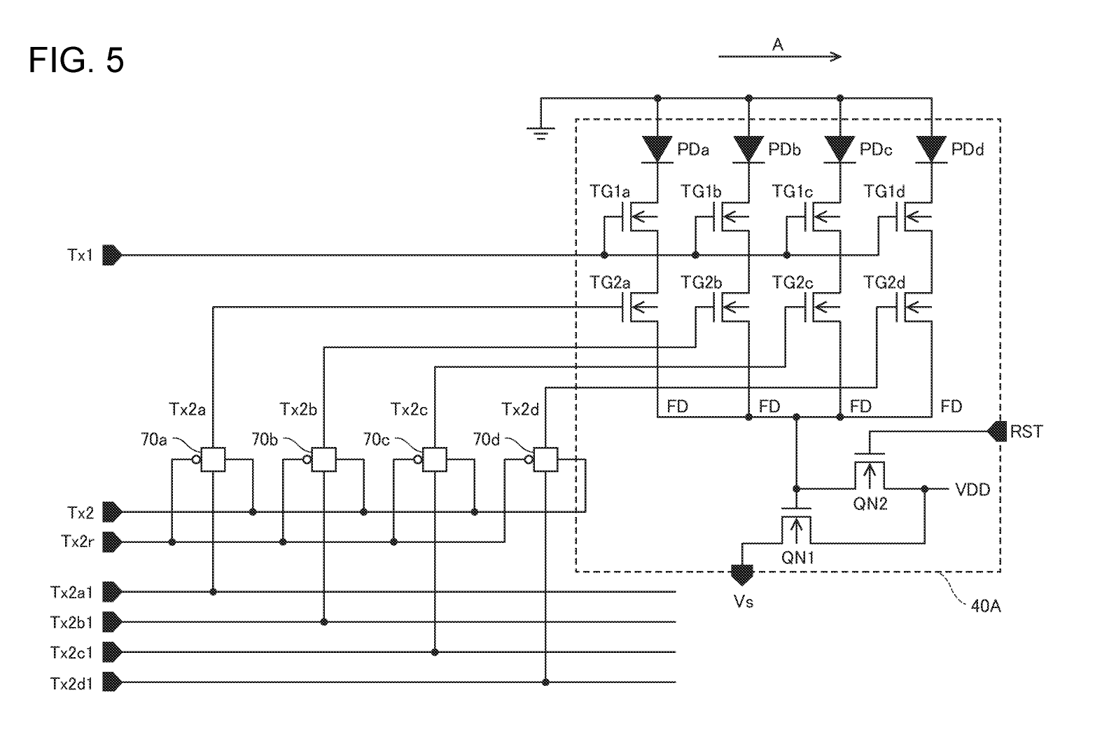

FIG. 5 is a circuit diagram illustrating an example of a unit block of the pixel unit and the read-out circuit unit in the line sensor. As shown in FIG. 5, four photodiodes PDa to PDd that are arranged successively in the main scanning direction A, and the read-out circuit unit for reading out pieces of pixel information by converting signal charges transferred from the photodiodes PDa to PDd to signal voltages constitute one unit block 40A. The number of unit blocks 40A provided in one line sensor is 216, for example.

The read-out circuit unit in the unit block 40A includes four pre-stage transfer gates TG1a to TG1d, four post-stage transfer gates TG2a to TG2d, one buffer transistor QN1, and one reset transistor QN2. That is, one buffer transistor QN1 and one reset transistor QN2 are shared between the four photodiodes PDa to PDd.

Here, the four pre-stage transfer gates TG1a to TG1d are controlled to be turned on at the same time irrespective of resolution modes. On the other hand, because the four photodiodes PDa to PDd each constitute one pixel, the four post-stage transfer gates TG2a to TG2d are controlled to be turned on at different timings. Accordingly, four output voltages respectively corresponding to the signal charges of the four photodiodes PDa to PDd are output from the unit block 40A in a time division manner.

A control signal Tx1 that is supplied to the four pre-stage transfer gates TG1a to TG1d in common, and four control signals Tx2a to Tx2d that are respectively supplied to the four post-stage transfer gates TG2a to TG2d are shown in FIG. 5. The common control signal Tx1 is supplied in order to turn on the four pre-stage transfer gates TG1a to TG1d at the same time, as described above.

Here, the control signal Tx1 supplied to the pre-stage transfer gates TG1a to TG1d and the control signals Tx2a to Tx2d respectively supplied to the post-stage transfer gates TG2a to TG2d may have different levels of high level potential. For example, the high level of the control signal Tx1 that is supplied to the pre-stage transfer gates TG1a to TG1d is higher than the power supply potential VDD.

That is, as a result of supplying the control signal Tx1 having higher potential than the power supply potential VDD to the pre-stage transfer gates TG1a to TG1d, the charge transfer capability of the pre-stage transfer gates TG1a to TG1d when turned on is not saturated at an exposure intensity that is less than or equal to a prescribed value, or the saturation level can be improved. Accordingly, the signal charges accumulated in the photodiodes PDa to PDd can be transferred with high transfer capability, and an image having a high contrast can be formed.

On the other hand, the control signals Tx2a to Tx2d are respectively supplied to the post-stage transfer gates TG2a to TG2d from CMOS logic circuits 70a to 70d, as shown in FIG. 5. The CMOS logic circuits 70a to 70d are turned on based on block selection signals Tx2 and Tx2r for selecting the unit block 40A, and supply timing signals Tx2a1 to Tx2d1 to the unit block 40A as control signals Tx2a to Tx2d. At this time, the control signals Tx2a to Tx2d are generated without causing a voltage drop, and therefore the transfer capability of the post-stage transfer gates TG2a to TG2d can be improved.

Although an analog switch (transmission gate) constituted by a P-channel MOS transistor and an N-channel MOS transistor is used as each of the CMOS logic circuits 70a to 70d in FIG. 5, the configuration of the CMOS logic circuits 70a to 70d is not limited thereto. For example, a circuit that does not cause a voltage drop such as a clocked CMOS logic circuit or an AND gate circuit can be used as each of the CMOS logic circuits 70a to 70d.

### First Embodiment

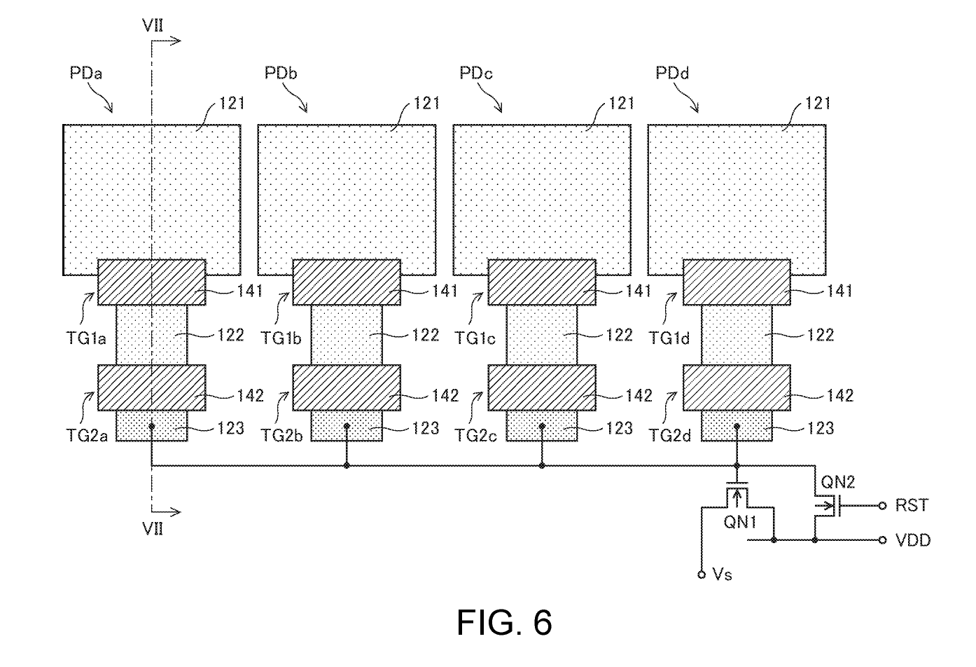

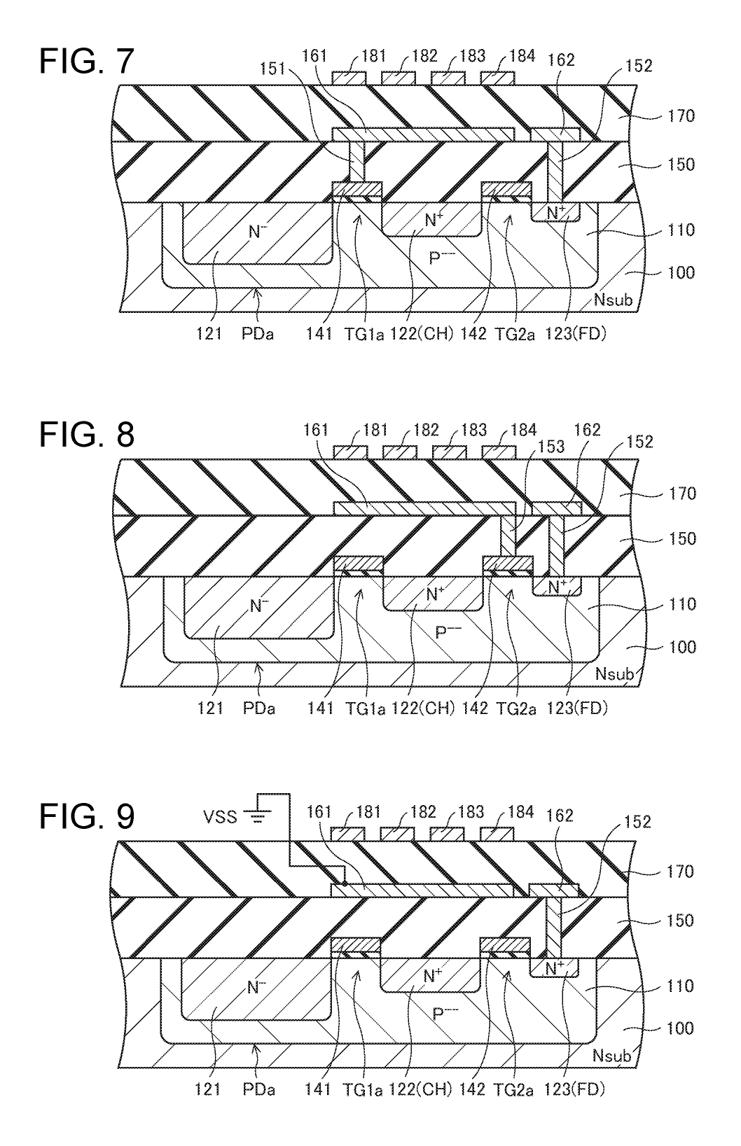

FIG. 6 is a plan view of a portion of a solid-state image capturing device according to a first embodiment of the invention, and FIG. 7 is a cross-sectional view taken along line VII-VII in FIG. 6. The solid-state image capturing device according to the first embodiment is a line sensor in which a plurality of pixels are arranged in a row. A configuration of the unit block of the pixel unit and the read-out circuit unit shown in FIG. 5 is shown in FIG. 6.

As shown in FIGS. 6 and 7, the solid-state image capturing device includes an N-type semiconductor substrate (Nsub) 100, a P-well (P⁻⁻) 110 formed in the semiconductor substrate 100, and an N-type impurity region (N⁻) 121, a charge holding region (CH) 122, and a floating diffusion region (FD) 123 that are formed in the P-well 110. The charge holding region 122 and the floating diffusion region 123 are N-type impurity regions (N⁺) with high concentrations.

A silicon (Si) substrate including N-type impurities such as phosphorus (P) or arsenic (As) is used as the semiconductor substrate 100, for example. Also, the P-well 110 is formed by implanting P-type impurity ions such as boron (B) into the semiconductor substrate 100 and thermally diffusing the impurities by performing heat treatment.

The photodiode PDa has an anode constituted by the P-well 110 and a cathode constituted by the N-type impurity region 121. A P-type impurity region (pinning layer) having high concentration may be arranged in an upper portion of the N-type impurity region 121 or the charge holding region 122. In the case of providing a pinning layer, a dark current generated in the N-type impurity region 121 or the charge holding region 122 can be reduced.

In this way, the solid-state image capturing device includes the light receiving element (photodiode PDa), the charge holding region 122, and the floating diffusion region 123 that are arranged in the semiconductor substrate 100. Also, the solid-state image capturing device includes the pre-stage transfer gate TG1a having a gate electrode 141 that is arranged on a region between the light receiving element and the charge holding region 122 in the semiconductor substrate 100 via a gate insulating film, and the post-stage transfer gate TG2a having a gate electrode 142 that is arranged on a region between the charge holding region 122 and the floating diffusion region 123 in the semiconductor substrate 100 via a gate insulating film.

The gate electrodes 141 and 142 are made of polysilicon that has been doped with impurities so as to be conductive, or the like, for example. Also, the buffer transistor QN1 and the reset transistor QN2 are also shown in FIG. 6.

Furthermore, the solid-state image capturing device includes an interconnect layer including interconnects (signal interconnect and control interconnect) that are arranged on the semiconductor substrate 100 via a plurality of interlayer insulating films, and a light shielding film that is arranged on the semiconductor substrate 100 side relative to the interconnect layer and shields the charge holding region 122 from light. That is, the light shielding film is arranged between the interconnects of the interconnect layer and the semiconductor substrate 100. Here, the number of interlayer insulating films may be two, or three or more.

In FIG. 7, an interlayer insulating film 150 arranged on the semiconductor substrate 100, a shielding layer including a light shielding film 161 arranged on the interlayer insulating film 150, an interlayer insulating film 170 arranged on the interlayer insulating film 150 and the shielding layer, and an interconnect layer including interconnects (signal interconnect and control interconnect) 181 to 184 that are arranged on the interlayer insulating film 170 are illustrated, as an example. The light shielding film 161 is arranged on the semiconductor substrate 100 side relative to the interconnect layer, and shields the charge holding region 122 from light.

The interlayer insulating films 150 and 170 are made of BPSG (Boron Phosphorus Silicon Glass), silicon oxide (SiO₂), or the like, for example. Also, the light shielding film 161 and the interconnects 181 to 184 include aluminum (Al), copper (Cu), or the like, for example.

According to the configuration described above, as a result of arranging the light shielding film 161 on the semiconductor substrate 100 side relative to the interconnect layer, the light shielding property of the charge holding region 122 can be improved, and the fluctuation in the amount of signal charges due to light that is incident on the charge holding region 122 can be reduced. Also, the capacitive coupling between the charge holding region 122 and the interconnects 181 to 184 in the interconnect layer can be reduced, and therefore the variation in the transfer characteristics that is caused by the potential of the charge holding region being influenced by the change in potential of the interconnects in the interconnect layer can be reduced.

Also, the photodiodes PDb to PDd and the like shown in FIG. 6 are configured similarly to the photodiode PDa and the like shown in FIG. 7. Accordingly, the solid-state image capturing device includes, in the unit block shown in FIG. 6, four light receiving elements (photodiodes PDa to PDd) that are arranged in a row, four charge holding regions 122 that are arranged corresponding to the four light receiving elements, four floating diffusion regions 123, four pre-stage transfer gates TG1a to TG1d, and four post-stage transfer gates TG2a to TG2d.

The four floating diffusion regions 123 are electrically connected to the gate electrode of one buffer transistor QN1. Furthermore, the solid-state image capturing device includes a shielding layer that shields the four charge holding regions 122. In this case, one shielding layer can shield the four charge holding regions 122. For example, the shielding layer includes four light shielding films 161 that respectively shield the four charge holding regions 122 from light.

A plurality of contact plugs 151 and 152 that include tungsten (W), aluminum (Al), copper (Cu), or the like are respectively arranged in the contact holes formed in the interlayer insulating film 150, for example.

In the first embodiment, the light shielding film 161 is electrically connected to the gate electrode 141 of the pre-stage transfer gate TG1a via the contact plug 151. In that case, when a control signal at a high level is supplied to the gate electrode 141 of the pre-stage transfer gate TG1a, and the pre-stage transfer gate TG1a is turned on, the potential of the charge holding region 122 increases due to the influence of the electric field formed by the light shielding film 161, and therefore it is easier to transfer electrons having negative charge from the light receiving element (photodiode PDa, for example) to the charge holding region 122.

Note that, a signal interconnect 162 may be arranged in the shielding layer. The signal interconnect 162 electrically connects the floating diffusion region 123 and the gate electrode of the buffer transistor QN1 (FIG. 6) via the contact plug 152.

### Second Embodiment

FIG. 8 is a cross-sectional view of a portion of a solid-state image capturing device according to a second embodiment of the invention. In the second embodiment, the light shielding film 161 is electrically connected to the gate electrode 142 of the post-stage transfer gate TG2a via the contact plug 153 arranged in a contact hole in the interlayer insulating film 150. In other respects, the second embodiment may be configured similarly to the first embodiment.

In that case, when a control signal at a high level is supplied to the gate electrode 141 of the pre-stage transfer gate TG1a, and the pre-stage transfer gate TG1a is turned on, a control signal at a low level is supplied to the gate electrode 142 of the post-stage transfer gate TG2a. Therefore, the influence of the change in potential of the interconnects 181 to 184 above the light shielding film 161 exerted on the potential of the charge holding region 122 can be reduced, and the potential distribution in the charge holding region 122 can be stabilized.

### Third Embodiment

FIG. 9 is a cross-sectional view of a portion of a solid-state image capturing device according to a third embodiment of the invention. In the third embodiment, the light shielding film 161 is electrically connected to an interconnect, in the shielding layer or the interconnect layer, to which the low potential side power supply potential VSS is supplied. In other respects, the third embodiment may be configured similarly to the first embodiment.

In that case, the potential of the light shielding film 161 is constant, and therefore the influence of the change in potential of the interconnects 181 to 184 above the light shielding film 161 exerted on the potential of the charge holding region 122 can be reduced, and the potential distribution in the charge holding region 122 can be stabilized.

### Modification of First Embodiment

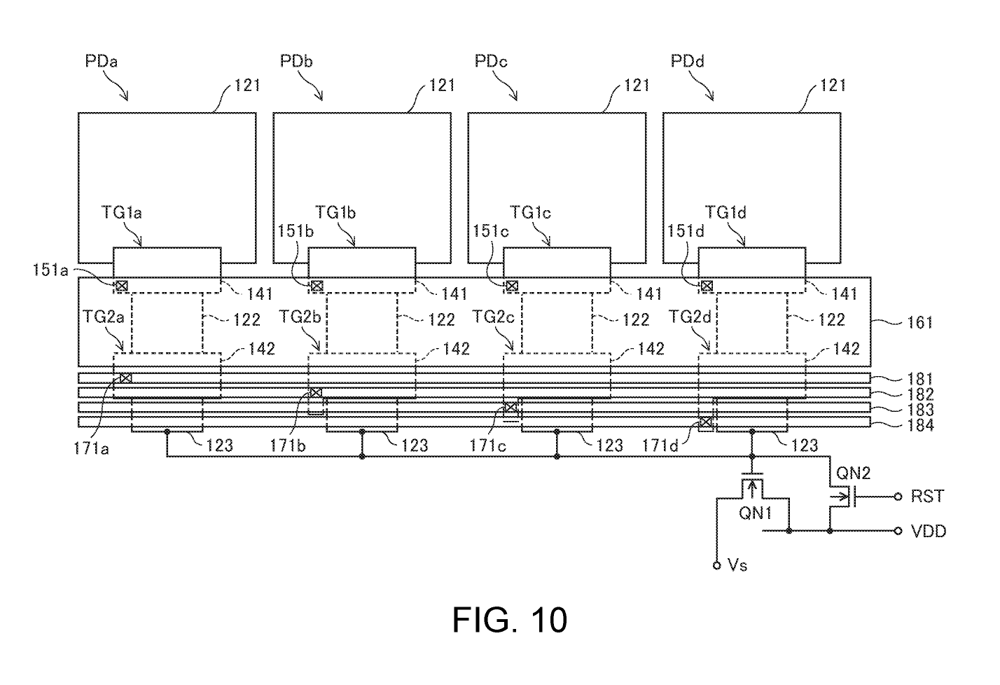

FIG. 10 is a plan view of a portion of a solid-state image capturing device according to a modification of the first embodiment of the invention. In FIG. 10, a specific exemplary arrangement of the light shielding film 161 and the interconnects 181 to 184 is shown in addition to the constitutional elements shown in FIG. 6. In other respects, the modification of the first embodiment may be configured similarly to the first embodiment.

The light shielding film 161 arranged in the shielding layer on the interlayer insulating film 150 (FIG. 7) is electrically connected to the gate electrodes 141 of the pre-stage transfer gates TG1a to TG1d via the contact plugs 151a to 151d respectively arranged in the contact holes in the interlayer insulating film 150. Accordingly, a plurality of charge holding regions 122 can be shielded from light by one light shielding film 161.

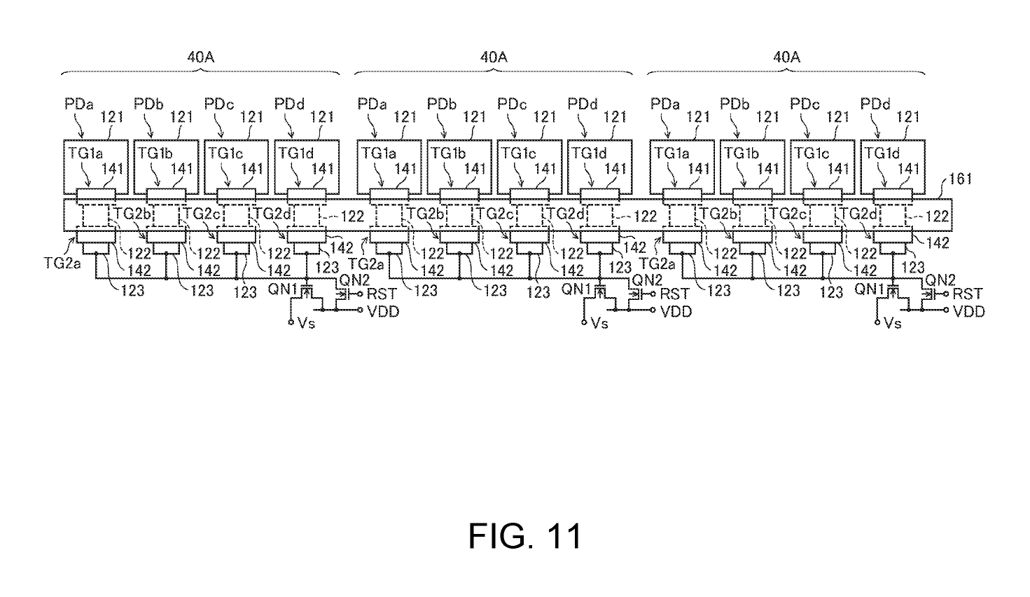

Furthermore, the light shielding film 161 may be continuously arranged over a plurality of unit blocks 40A, as shown in FIG. 11. Accordingly, the charge holding regions 122 of the plurality of unit blocks 40A can be shielded by the one light shielding film 161. In that case, the light shielding film 161 is commonly connected to the gate electrodes 141 of the pre-stage transfer gates TG1a to TG1d in the plurality of unit blocks 40A.

Also, the interconnects 181 to 184 arranged in the interconnect layer on the interlayer insulating film 170 (FIG. 7) are respectively electrically connected to the gate electrodes 142 of the post-stage transfer gates TG2a to TG2d via contact plugs 171a to 171d respectively arranged in contact holes in the interlayer insulating film 170 and four contact plugs (not shown) respectively arranged in contact holes in the interlayer insulating film 150. Accordingly, the post-stage transfer gates TG2a to TG2d can be separately controlled.

### Modification of Second Embodiment

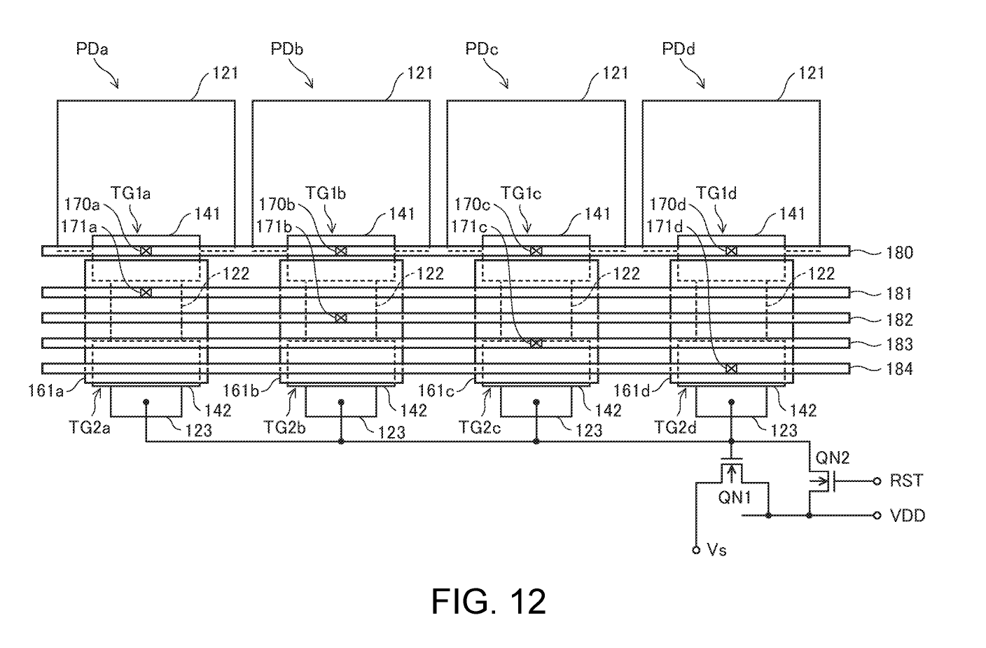

FIG. 12 is a plan view of a portion of a solid-state image capturing device according to a modification of the second embodiment of the invention. In FIG. 12, a specific exemplary arrangement of light shielding films 161a to 161d and interconnects 180 to 184 is shown in addition to the constitutional element shown in FIG. 6. In other respects, the modification of the second embodiment may be configured similarly to the second embodiment.

The interconnect 180 arranged in the interconnect layer on the interlayer insulating film 170 (FIG. 8) is electrically connected to the gate electrodes 141 of the pre-stage transfer gates TG1a to TG1d via contact plugs 170a to 170d respectively arranged in contact holes in the interlayer insulating film 170 and four contact plugs (not shown) respectively arranged in contact holes in the interlayer insulating film 150.

The interconnects 181 to 184 arranged in the interconnect layer on the interlayer insulating film 170 are respectively electrically connected to the light shielding films 161a to 161d arranged in the shielding layer on the interlayer insulating film 150 (FIG. 8) via the contact plugs 171a to 171d respectively arranged in contact holes in the interlayer insulating film 170.

Furthermore, the light shielding films 161a to 161d are respectively electrically connected to the gate electrodes 142 of the post-stage transfer gates TG2a to TG2d via four contact plugs (not shown) respectively arranged in contact holes in the interlayer insulating film 150. Accordingly, the post-stage transfer gates TG2a to TG2d can be separately controlled.

### Modification of Third Embodiment

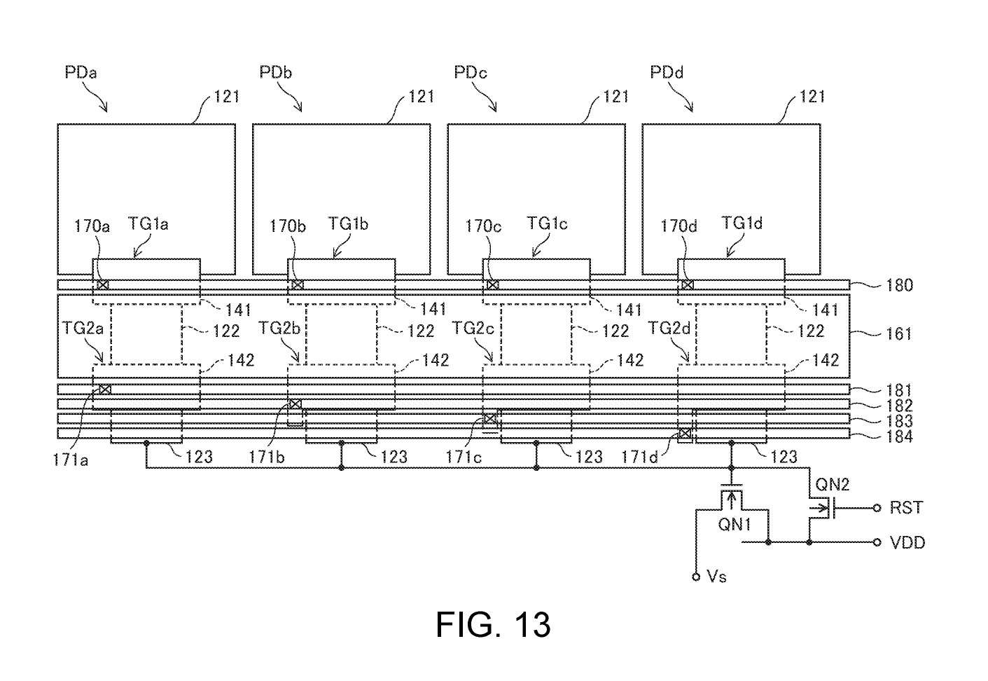

FIG. 13 is a plan view of a portion of a solid-state image capturing device according to a modification of the third embodiment of the invention. In FIG. 13, a specific exemplary arrangement of the light shielding film 161 and the interconnects 180 to 184 is shown in addition to the constitutional elements shown in FIG. 6. In other respects, the modification of the third embodiment may be configured similarly to the third embodiment.

The interconnect 180 arranged in the interconnect layer on the interlayer insulating film 170 (FIG. 9) is electrically connected to the gate electrodes 141 of the pre-stage transfer gates TG1a to TG1d via contact plugs 170a to 170d respectively arranged in contact holes in the interlayer insulating film 170 and four contact plugs (not shown) respectively arranged in contact holes in the interlayer insulating film 150.

The light shielding film 161 arranged in the shielding layer on the interlayer insulating film 150 (FIG. 9) is electrically connected to an interconnect, in the shielding layer or the interconnect layer, to which the low potential side power supply potential VSS is supplied (refer to FIG. 9). Accordingly, a plurality of charge holding regions 122 can be shielded from light by one light shielding film 161.

Furthermore, the light shielding film 161 may be continuously arranged over a plurality of unit blocks 40A, as shown in FIG. 11. Accordingly, the charge holding regions 122 of the plurality of unit blocks 40A can be shielded from light by the one light shielding film 161. In that case, the light shielding film 161 is commonly connected to an interconnect to which the low potential side power supply potential VSS is supplied, in the plurality of unit blocks 40A.

Also, the interconnects 181 to 184 arranged in the interconnect layer on the interlayer insulating film 170 are respectively electrically connected to the gate electrodes 142 of the post-stage transfer gates TG2a to TG2d via contact plugs 171a to 171d respectively arranged in contact holes in the interlayer insulating film 170 and four contact plugs (not shown) respectively arranged in contact holes in the interlayer insulating film 150. Accordingly, the post-stage transfer gates TG2a to TG2d can be separately controlled.

### Fourth Embodiment

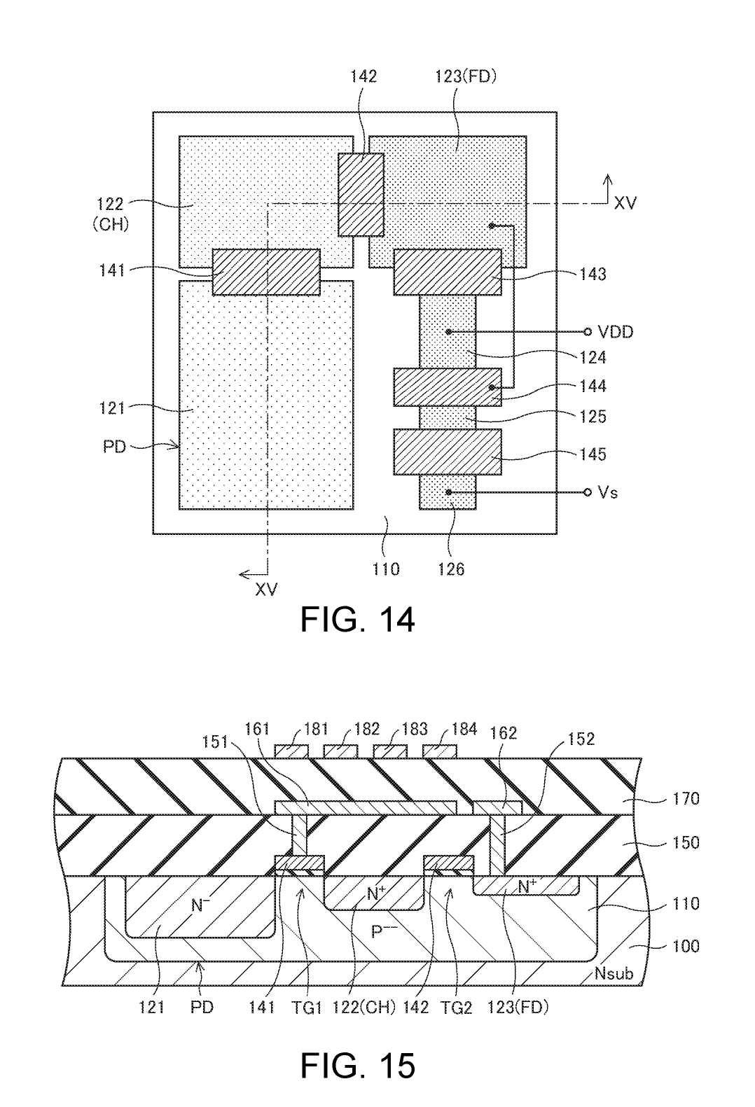

FIG. 14 is a plan view of a portion of a solid-state image capturing device according to a fourth embodiment of the invention, and FIG. 15 is a cross-sectional view taken along line XV-XV in FIG. 14. The solid-state image capturing device according to the fourth embodiment is an area sensor in which a plurality of pixels are arrayed in a two-dimensional matrix. The configuration of a pixel unit and a read-out circuit unit corresponding to one pixel is shown in FIG. 14, and the equivalent circuit thereof is similar to the equivalent circuit shown in FIG. 4.

The area sensor includes pixel units and read-out circuit units that are arranged in a plurality of lines, and signal charges are transferred from the light receiving elements in these lines to the respective charge holding regions CH (hereinafter, refer to FIG. 4) at the same time. This function is referred to as global shutter (electronic shutter).

Thereafter, signal charges held in the charge holding regions CH in the line that is sequentially selected are transferred to the respective floating diffusion regions FD, the selection transistors QN3 are turned on, and output voltages of the buffer transistors QN1 are output to output terminals of the respective read-out circuit units via the selection transistors QN3.

As shown in FIGS. 14 and 15, this solid-state image capturing device includes the N-type semiconductor substrate (Nsub) 100, the P-well (P⁻⁻) 110 formed in the semiconductor substrate 100, and the N-type impurity regions 121 and 124 to 126, the charge holding regions (CH) 122, and the floating diffusion region (FD) 123 that are formed in the P-well 110. The photodiode PD has an anode constituted by the P-well 110 and a cathode constituted by the N-type impurity region (N⁻) 121.

The floating diffusion region 123 shown in FIG. 14 constitutes a source of the reset transistor QN2. Also, the N-type impurity region 124 constitutes a drain of the reset transistor QN2 and a drain of the buffer transistor QN1. The N-type impurity region 125 constitutes a source of the buffer transistor QN1 and a drain of the selection transistor QN3. The N-type impurity region 126 constitutes a source of the selection transistor QN3.

The gate electrode 141 of the pre-stage transfer gate TG1 is arranged, via a gate insulating film, on a region between the N-type impurity region 121 and the charge holding region 122 in the semiconductor substrate 100 in which the P-well 110 is formed. The gate electrode 142 of the post-stage transfer gate TG2 is arranged, via a gate insulating film, on a region between the charge holding region 122 and the floating diffusion region 123 in the semiconductor substrate 100.

Similarly, the gate electrode 143 of the reset transistor QN2 is arranged, via a gate insulating film, on a region between the floating diffusion region 123 and the N-type impurity region 124. The gate electrode 144 of the buffer transistor QN1 is arranged, via a gate insulating film, on a region between the N-type impurity region 124 and the N-type impurity region 125. The gate electrode 145 of the selection transistor QN3 is arranged, via a gate insulating film, on a region between the N-type impurity region 125 and the N-type impurity region 126. The gate electrodes 141 to 145 are made of polysilicon doped with impurities so as to be conductive, or the like, for example.

Furthermore, the solid-state image capturing device includes, as shown in FIG. 15, the interlayer insulating film 150 arranged on the semiconductor substrate 100, the shielding layer including the light shielding film 161 that is arranged on the interlayer insulating film 150, the interlayer insulating film 170 that is arranged on the interlayer insulating film 150 and the shielding layer, and the interconnect layer including the interconnects 181 to 184 that is arranged on the interlayer insulating film 170. The light shielding film 161 is arranged on the semiconductor substrate 100 side relative to the interconnect layer and shields the charge holding region 122.

In FIG. 15, similarly to the first embodiment, the light shielding film 161 is electrically connected to the gate electrode 141 of the pre-stage transfer gate TG1 via the contact plug 151 arranged in a contact hole in the interlayer insulating film 150. Alternatively, the light shielding film 161 may be electrically connected to the gate electrode 142 of the post-stage transfer gate TG2 similarly to the second embodiment, or may be electrically connected to an interconnect to which the low potential side power supply potential is supplied, similarly to the third embodiment.

### Modification of Fourth Embodiment

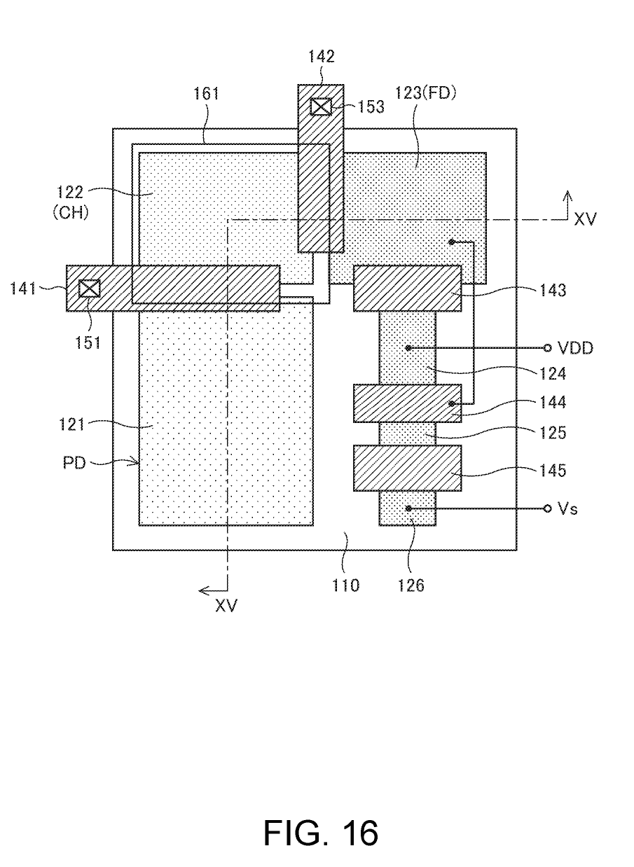

FIG. 16 is a plan view of a portion of a solid-state image capturing device according to a modification of the fourth embodiment of the invention. In FIG. 16, in addition to the constitutional elements shown in FIG. 14, a specific exemplary arrangement of the light shielding film 161 is shown, and the layout of the gate electrodes 141 and 142 is changed. In other respects, the modification of the fourth embodiment may be configured similarly to the fourth embodiment.

In the example shown in FIG. 16, the light shielding film 161 arranged in the shielding layer on the interlayer insulating film 150 (FIG. 15) is arranged so as to completely cover the charge holding region 122 in plan view, and shields the charge holding region 122 from light. Note that, in the present application, “in plan view” refers to viewing portions in a direction vertical to the principal surface (upper surface in FIG. 15) of the semiconductor substrate 100 in a see-through manner.

Therefore, in the case where the light shielding film 161 is electrically connected to the gate electrode 141 of the pre-stage transfer gate TG1 (FIG. 15) or the interconnect to which the low potential side power supply potential is supplied, the gate electrode 142 of the post-stage transfer gate TG2 (FIG. 15) is arranged so as to protrude outward from the light shielding film 161 in plan view. In this way, the gate electrode 142 can be electrically connected to the interconnect in the upper layer via the contact plug 153 arranged in a contact hole in the interlayer insulating film 150.

On the other hand, in the case where the light shielding film 161 is electrically connected to the gate electrode 142 of the post-stage transfer gate TG2 (FIG. 15) or the interconnect to which the low potential side power supply potential is supplied, the gate electrode 141 of the pre-stage transfer gate TG1 (FIG. 15) is arranged so as to protrude outward from the light shielding film 161 in plan view. In this way, the gate electrode 141 can be electrically connected to the interconnect in the upper layer via the contact plug 151 arranged in a contact hole in the interlayer insulating film 150.

### Fifth Embodiment

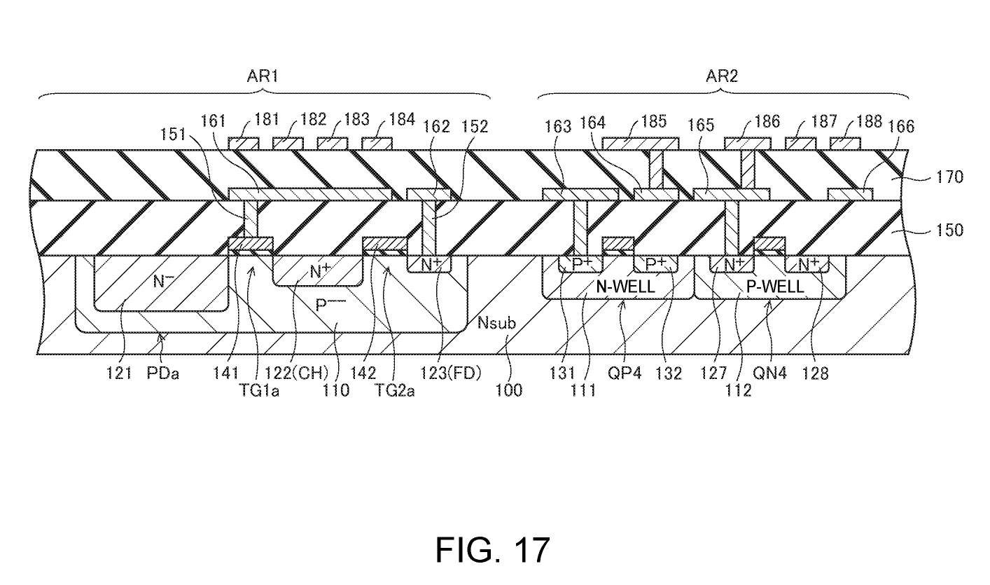

Next, a solid-state image capturing device according to a fifth embodiment of the invention will be described. FIG. 17 is a cross-sectional view of the solid-state image capturing device according to the fifth embodiment of the invention. The solid-state image capturing device may be a line sensor, or may be an area sensor. In the following, the case of the solid-state image capturing device being a line sensor will be described as an example.

In FIG. 17, a first region AR1 in which the pixel unit and the read-out circuit unit are arranged and a second region AR2 in which a logic circuit is arranged are illustrated. The configuration of the pixel unit and the read-out circuit unit in the first region AR1 shown in FIG. 17 is similar to the configuration of the pixel unit and the read-out circuit unit shown in FIG. 7. A P-channel MOS transistor QP4 and an N-channel MOS transistor QN4 that are used in the logic circuit are provided in the second region AR2. For example, the transistors QP4 and QN4 constitute any of the CMOS logic circuits 70a to 70d shown in FIG. 5.

In the second region AR2, an N-well 111 and a P-well 112 are formed in the semiconductor substrate 100. P-type impurity regions (P⁺) 131 and 132 that constitute a source and a drain of the transistor QP4 are formed in the N-well 111, and N-type impurity regions (N⁺) 127 and 128 that constitute a source and a drain of the transistor QN4 are formed in the P-well 112.

Also, in the second region AR2, a first interconnect layer including interconnects 163 to 166 is arranged on the interlayer insulating film 150, and a second interconnect layer including interconnects 185 to 188 is arranged on the interlayer insulating film 170. The interconnects 163 to 166 and 185 to 188 include aluminum (Al), copper (Cu), or the like.

In this way, the solid-state image capturing device further includes the interconnects 163 to 166, in the second region AR2 in which the logic circuit is arranged, that are arranged at the same height as the light shielding film 161. In that case, the manufacturing process of the solid-state image capturing device can be simplified by forming the light shielding film 161 and the interconnects 163 to 166 in the logic circuit at the same time. Note that, in the present application, “height” refers to the height from the principal surface (upper surface in the diagram) of the semiconductor substrate 100.

On the other hand, the light shielding film 161 may be arranged in a layer that is different from the interconnect layer in the second region AR2 in which the logic circuit is arranged. In that case, for example, as a result of arranging the light shielding film 161 at a position that is lower than the interconnects in the logic circuit, the light shielding property of the charge holding region 122 can be further improved, or the capacitive coupling between the interconnects 181 to 184 in the interconnect layer and the charge holding region 122 can be further reduced.

Example of Light Shielding Film

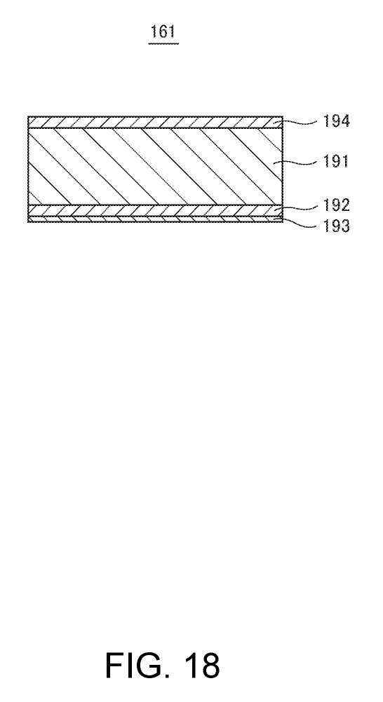

Next, an example of the light shielding film used in the first to fifth embodiments of the invention will be described with reference to FIGS. 7 and 18. FIG. 18 is a cross-sectional view illustrating the example of the light shielding film. The light shielding film 161 as shown in FIG. 18 may be used in the first to fifth embodiments of the invention.

The light shielding film 161 shown in FIG. 18 includes a first layer 191 including aluminum (Al) or copper (Cu) and a second layer 192 that is arranged on the first layer 191 on the semiconductor substrate 100 side of the first layer 191 and includes titanium nitride (TiN). Titanium nitride (TiN) has lower light reflectivity than aluminum (Al), copper (Cu), or an alloy thereof.

Accordingly, as a result of arranging the second layer 192 including titanium nitride (TiN) on the first layer 191 on the semiconductor substrate 100 side of the first layer 191, the amount of light that is incident on the charge holding region 122 after having passed through the interlayer insulating films 170 and 150, having been reflected off the principal surface of the semiconductor substrate 100, and thereafter being reflected again off a lower surface of the light shielding film 161 can be reduced. The film thickness of the second layer 192 is desirably in a range from 500 Å to 800 Å (50 nm to 80 nm). Accordingly, the second layer 192 has the necessary and sufficient film thickness in order for exerting a property of titanium nitride (TiN) off which light is unlikely to reflect.

Also, the light shielding film 161 may further include a third layer 193 that is arranged on the second layer 192 on the semiconductor substrate 100 side of the second layer 192 and includes titanium (Ti). In that case, the bondability of the second layer 192 including titanium nitride (TiN) to a base layer can be improved by the third layer 193 including titanium (Ti). The film thickness of the third layer 193 is desirably in a range from 100 Å to 250 Å (10 nm to 25 nm). Accordingly, the third layer 193 improves the bondability of the second layer 192 to the base layer, and is unlikely to influence the reflection characteristic of the second layer 192.

Furthermore, the light shielding film 161 may further include a fourth layer 194 that is arranged on the first layer 191 on the side thereof opposite to the semiconductor substrate 100, and includes titanium nitride (TiN). As a result of providing the fourth layer 194, light reflected from the light shielding film 161 can be reduced when a photo resist is exposed in a photolithography step when the solid-state image capturing device is manufactured. The film thickness of the fourth layer 194 is desirably in a range from 500 Å to 800 Å (50 nm to 80 nm), similarly to the film thickness of the second layer 192. Note that the interconnects (interconnects 162 to 166 shown in FIG. 17, for example) that are arranged at the same height as the light shielding film 161 may be configured similarly to the light shielding film 161.

As described in the first to fifth embodiments, as a result of using the solid-state image capturing device in which the fluctuation in the amount of signal charges due to light that is incident on the charge holding region 122 is reduced, and the variation in the transfer characteristic that is caused by the potential of the charge holding region 122 being influenced by the change in potential of the interconnects 181 to 184 in the interconnect layer is reduced, an electronic apparatus in which image quality of image data that is obtained by capturing an image of a subject can be improved can be provided.

Also, the solid-state image capturing devices according to the first to fifth embodiments can be applied, other than the scanner device, to electronic apparatuses that capture a subject and generate image data, such as a drive recorder, a digital movie camera, a digital still camera, a mobile terminal such as a mobile phone, a TV phone, a surveillance television monitor, a measurement apparatus, and a medical apparatus, for example.

In the embodiments described above, a case where the N-type impurity region and the like are formed in the P-type semiconductor layer was described, but the invention is not limited to the embodiments described above. For example, the invention can also be applied to a case where a P-type impurity region and the like are formed in an N-type semiconductor layer. In this way, many modifications can be made within the technical idea of the invention by a person having ordinary skill in the art.

This application claims priority from Japanese Patent Applications No. 2016-180603 filed in the Japanese Patent Office on Sep. 15, 2016, and No. 2017-107554 filed in the Japanese Patent Office on May 31, 2017, the entire disclosure of which is hereby incorporated by reference in its entirely.

What is claimed is:

1. A solid-state image capturing device comprising:
a light receiving element, a charge holding region, and a floating diffusion region that are arranged in a semiconductor substrate;
a first transfer gate including a gate electrode that is arranged on a region between the light receiving element and the charge holding region in the semiconductor substrate via a gate insulating film;
a second transfer gate including a gate electrode that is arranged on a region between the charge holding region and the floating diffusion region in the semiconductor substrate via a gate insulating film;
an interconnect layer including an interconnect that is arranged on the semiconductor substrate via a plurality of interlayer insulating films; and
a light shielding film that is arranged on the semiconductor substrate side relative the interconnect layer, and shields the charge holding region from light.

2. The solid-state image capturing device according to claim 1, wherein the light shielding film is electrically connected to the gate electrode of the first transfer gate.

3. The solid-state image capturing device according to claim 1, wherein the light shielding film is electrically connected to the gate electrode of the second transfer gate.

4. The solid-state image capturing device according to claim 1, wherein the light shielding film is electrically connected to an interconnect to which a low potential side power supply potential is supplied.

5. The solid-state image capturing device according to claim 1, comprising:
four light receiving elements that are arranged in a row;
four charge holding regions, four floating diffusion regions, four first transfer gates, and four second transfer gates that are arranged corresponding to the four light receiving elements; and
a shielding layer that shields the four charge holding regions from light,
wherein the four floating diffusion regions are electrically connected to a gate electrode of one buffer transistor.

6. The solid-state image capturing device according to claim 1, further comprising:
an interconnect that is arranged at the same height as the light shielding film, in a region in which a logic circuit is arranged.

7. The solid-state image capturing device according to claim 1, wherein the light shielding film is arranged in a layer that is different from an interconnect layer in a region in which a logic circuit is arranged.

8. The solid-state image capturing device according to claim 1, wherein the light shielding film includes a first layer including aluminum or copper, and a second layer that is arranged on the first layer on the semiconductor substrate side of the first layer and includes titanium nitride.

9. The solid-state image capturing device according to claim 8, wherein a film thickness of the second layer is in a range from 50 nm to 80 nm.

10. The solid-state image capturing device according to claim 8, wherein the light shielding film further includes a third layer that is arranged on the second layer on the semiconductor substrate side of the second layer and includes titanium.

11. An electronic apparatus comprising the solid-state image capturing device according to claim 1.
